(19) United States
(12) Patent Application Publication
(10) Pub. No.: US 2016/0181066 A1
(43) Pub. Date: Jun. 23, 2016

(54) LAMINATED MATERIALS, METHODS AND APPARATUS FOR MAKING SAME, AND USES THEREOF

(71) Applicant: NITRIDE SOLUTIONS, INC., Wichita, KS (US)

(72) Inventors: Daniel Brors, Discovery Bay, CA (US); Richard Ernest DeMaray, Portola Valley, CA (US); David Slutz, Bethlehem, PA (US); Richard Clark, Charlotte, NC (US)

(21) Appl. No.: 14/879,865

(22) PCT Filed: Oct. 16, 2013
(86) PCT No.: PCT/EP2013/071640

§ 371 Date: Oct. 9, 2015

Related U.S. Application Data
(63) Continuation-in-part of application No. 14/348,406, filed on Mar. 28, 2014.
(60) Provisional application No. 61/540,558, filed on Sep. 29, 2011.
(60) Provisional application No. 61/718,575, filed on Oct. 25, 2012.

(30) Foreign Application Priority Data
May 21, 2015 (EP) 13779559

(51) Int. Cl. H01J 37/317; H01M 4/04; H01M 4/38; H01M 4/66; C23C 14/22; H01M 4/134

(52) U.S. Cl. CPC H01J 37/3178; C23C 14/221; H01M 4/134; H01M 4/38; H01M 4/662; H01M 4/0404; H01J 2237/3321

(57) ABSTRACT

Systems and methods using PVD for producing materials, for example nitrides, are disclosed. The present application also relates to use of the materials for electrode materials.

### CROSS REFERENCE TO RELATED APPLICATIONS

The present application is a continuation in part of application U.S. patent application Ser. No. 14/348,406, entitled “Inorganic Materials, Methods And Apparatus For Making Same, And Uses”, filed Mar. 28, 2014 which is a National stage entry of PCT Application No. PCT/EP2012/069156, entitled “Inorganic Materials, Methods And Apparatus For Making Same, And Uses”, filed Sep. 27, 2012 and published as WO/2013/045596; which further claims the benefit of U.S. Provisional Application No. 61/540,558, filed on Sep. 29, 2011. The present application is also related to PCT Application No. PCT/EP2013/071640, entitled, “Laminated Materials, Methods And Apparatus For Making Same, And Uses”, filed Oct. 16, 2013; which further claims the benefit of U.S. Provisional Application No. 61/718,575, filed on Oct. 25, 2012, the contents of each above identified application is incorporated herein by reference in its entirety.

### FIELD OF THE PRESENT DISCLOSURE

This invention relates to laminated materials, methods and apparatus for making same, and uses thereof. In the following, reference is made to use of III-V semiconductors, in particular, but not exclusively, nitrides, but it will be clear to the person skilled in the art that the methods and apparatus is not limited thereto. The present invention relates to applying certain of the processes disclosed in PCT Application No. PCT/EP2012/069156 to make laminated materials. Such laminated materials may use the high thermal conductivity of MN or other deposited materials to form substrates for devices or heat spreaders to which devices are mounted.

### SUMMARY OF INVENTION

In a first aspect the present invention provides laminates of adherent coatings on flexible substrates.

In a second aspect the present invention provides apparatuses for manufacturing laminated materials by vapour deposition, using ion beam generators, as described herein.

In a third aspect the present invention provides electrodes for electrochemical devices, for example batteries, in which at least one active layer is an adherent layer formed by vapour deposition.

The scope of the invention is as claimed from time to time.

The present disclosure generally relates to method of manufacturing an article comprising at least one adherent coating on a flexible substrate, the method comprising the step of forming an ion beam and bombarding at least one flexible substrate with ions from the ion beam to form said adherent coating on the flexible substrate in which the ion beam is generated by an ion beam generator. The ion beam generator includes a first chamber housing one or more vapour generators capable of forming a vapour from one or more condensed phase sources of material, a second chamber adjacent the first chamber housing one or more plasma generators comprising one or more hollow cathodes having one or more open-ended channels extending therethrough, the channels comprising one or more channel walls and having a length extending from one end of the channel to another end of the channel to define one or more spaces and capable of forming plasma within said one or more spaces. The ion beam generator further includes one or more apertures between the first and second chambers arranged to permit vapour generated in the first chamber to enter the second chamber and the one or more vapour generators and one or more plasma generators being arranged whereby in operation, vapour generated in the first chamber by the one or more vapour generators may traverse the one or more spaces through plasma formed in the second chamber by the one or more plasma generators.

The present disclosure also related to: a method wherein the vapour generator is capable of evaporative formation of a vapour from one or more condensed phase sources of material; a method wherein the vapour generator comprises at least one electron beam generator, operable to direct an electron beam at the one or more condensed phase sources of material; and a method wherein the at least one electron beam generator is operable to magnetically bend electrons from the electron beam generator to the one or more condensed phase sources of material.

The present disclosure also related to: a method, wherein one or more of the one or more plasma generators further comprises one or more housings spaced from and electrically insulated from the one or more cathodes; a method, wherein one or more of the one or more plasma generators further comprises a source for a magnetic field configured to lie substantially parallel to the one or more channel walls for a substantial fraction of the length of the channel; a method wherein the source for a magnetic field comprises at least one first magnet situated proximal the vapour generator, and at least one second magnet situated distal the vapour generator.

The present disclosure also related to: a method wherein the source for a magnetic field comprises an electromagnet; a method wherein magnetic shielding is disposed between the vapour generator and the plasma generator; a method in which the substrate is a coated substrate having a surface coating, and the adherent coating forms on the surface coating; and a method in which further layers are applied to the adherent coating by the above method or otherwise.

The present disclosure relates to an apparatus for manufacturing by vapour deposition an article comprising at least one adherent coating on a flexible substrate, the apparatus comprising at least one ion beam generator further comprising a first chamber housing one or more vapour generators capable of forming a vapour from one or more condensed phase sources of material, a second chamber adjacent the first chamber housing one or more plasma generators comprising one or more cathodes having one or more open-ended channels extending therethrough. The channels of the generater comprising one or more channel walls and having a length extending from one end of the channel to another end of the channel to define one or more spaces and capable of forming plasma within said one or more spaces. The generator further including one or more apertures between the first and second chambers arranged to permit vapour generated in the first chamber to enter the second chamber and the one or more vapour generators and one or more plasma generators being arranged whereby in operation, vapour generated by the one or more vapour generators may traverse the one or more spaces through plasma formed by the one or more plasma generators.

The apparatus further including at least one gas supply operable to supply gas for conversion into plasma within the at least one ion beam generator and at least one substrate receiving region to receive at least one substrate, and permit passage of said substrate across said substrate receiving region and positioned to permit in use at least one substrate passing across the at least one substrate receiving region to be bombarded by ions from the at least one ion beam generator. The present application further relates to: an apparatus in which the substrate receiving region comprises a substrate mount permitting passage of the substrate across a support; an apparatus further comprising a source operable to apply a bias to a substrate passing across the substrate receiving region; and an apparatus wherein the source is operable to apply a radio frequency to a substrate passing across the substrate receiving region.

The present disclosure further relates to: an apparatus in which a heater is provided to heat the substrate; an apparatus comprising one or more vents situated between the plasma chamber and the substrate receiving region, and operable to admit gas close to the substrate receiving region; and an apparatus comprising a source operable to inject gas in the region of the one or more vapour generators to inhibit reaction between reactant gases and at least a surface of the condensed phase sources of material.

The present disclosure further relates to: an apparatus operable to provide a lower pressure in the first chamber than in the second chamber; an apparatus comprising a shutter selectively operable to inhibit transfer of vapour from the first chamber to the second chamber; an apparatus wherein one or more crucibles are provided to house said one or more condensed phase sources of material; and an apparatus comprising a feed spool for a flexible substrate and a take-up spool for the article comprising at least one adherent coating on a flexible substrate.

The present disclosure further relates to an article comprising at least one adherent coating on a flexible substrate and an article comprising a layer comprising MN and having a thermal conductivity in excess of 210 W/mK.

The present disclosure also relates to a device comprising one or more: electronic components; opto-electronic components; electro-acoustic components; MEMS components; and/or spintronic components mounted to an article.

The present disclosure also relates a laminate for use as an electrode for a battery, the laminate comprising an electrically conductive layer capable of acting as a current collector, and one or more layers comprising at least one active layer which comprises one or more solid phases active to absorb and desorb a charge carrying element in operation of the battery, characterized in that said at least one active layer is an adherent layer formed by vapour deposition.

The present disclosure also relates to a laminate in which the one or more solid phases are active to absorb and desorb lithium as the charge carrying element; a laminate in which the one or more solid phases comprise one or more elements, alloys and compounds which can form alloys or compounds with lithium; and a laminate in which the one or more solid phases comprise in elemental, alloy, or compound form, one or more of the elements B, Mg, Al, Si, Zn, Ga, Ge, As, Se, Pd, Ag, Cd, In, Sn, Sb, Te, Pt, Au, Hg, Tl, Pb, Bi.

The present disclosure also relates to a laminate in which the one or more solid phases comprise an alloy of one or more of said elements with one or more other alloying elements; a laminate in which the one or more solid phases comprise one or more alloys comprising at least one element selected from the group of Si, Sn, Sb, Ge, and Al, with at least one element selected from the group B, Mg, Zn, Ga, As, Se, Pd, Ag, Cd, In, Te, Pt, Au, Hg, Tl, Pb, Bi; and a laminate in which the one or more solid phases comprise one or more alloys comprising at least one element selected from the group of Si, Sn, Sb, Ge, and Al, with at least one element selected from the group B, Cr, Nb, Cu, Zr, Ag, Ni, Zn, Fe, Co, Mn, Sb, Zn, Ca, Mg, V, Ti, In, Al, Ge.

The present disclosure also relates to a laminate in which the one or more other alloying elements comprise at least one element forming part of the electrically conductive layer; a laminate in which the electrically conductive layer comprises copper and the one or more solid phases comprise the alloy Cu6Sn5; a laminate in which the one or more solid phases comprise an oxide; a laminate in which the active layer is discontinuous; and laminate in which the electrically conductive layer is capable of absorbing and desorbing a charge carrying element in operation of such a battery.

The present disclosure also relates to a laminate in which the electrically conductive layer comprises a laminate of a first electrically conductive layer and at least one second electrically conductive layer; and a laminate in which one or more of the first electrically conductive layer and at least one second electrically conductive layer is capable of absorbing and desorbing a charge carrying element in operation of such a battery.

The present disclosure also relates to A method of forming a laminate comprising the steps of forming an ion beam comprising one or more elements capable of forming alloys or compounds with an element used as a charge carrying element in a battery, and bombarding at least one electrically conductive substrate with ions from the ion beam to form said laminate of at least one active layer and said electrically conductive layer.

The present disclosure also relates to an electrode formed from a laminate and a battery comprising an electrode.

### BRIEF DESCRIPTION OF THE FIGURES

In the following non-limitative description reference is made to the drawings in which:

FIG. 1 is a schematic diagram of apparatus disclosed in PCT/EP2012/069156 published as WO/2013/045596 and usable in accordance with one aspect of the present invention;

FIG. 2 is a schematic diagram of a plasma generator usable in the apparatus of FIG. 1;

FIG. 3 is a schematic diagram of a vapour generator usable in the apparatus of FIG. 1;

FIG. 4 is a schematic diagram of the apparatus of FIG. 1 and associated equipment;

FIG. 5 is a schematic drawing of a modification of the apparatus of FIG. 1 in accordance with one aspect of the present invention.

FIG. 6 is a schematic drawing of a laminated material in accordance with the present invention.

FIGS. 7 and 8 are schematic drawings exemplifying use of the laminated product of FIG. 6.

### DESCRIPTION

### Definitions

In the following:

Relative positional terms such as “upper” “lower” and “beneath” are meant to indicate the relationships shown in the drawings and do not imply restrictions on the scope of the invention.

“Condensed phase” is to be interpreted as indicating solid, liquid or mixtures thereof.

“Ion beam” is to be taken as meaning a flow of gaseous/plasma material comprising ions but which may also contain neutral species.

“Flexible” is to be taken as meaning capable of being flexed or bent without breaking and in particular capable of being bent on to a former with a radius of less than 5 metres without breaking.

“Comprise” is to be taken as including both normal meanings, namely “to consist of” and “to include contain or embrace”. Where used with reference to a single object, the word does not exclude the presence of other objects, and when used with reference to a list the word does not imply that the list is exclusive.

### General Description of PVD Method and Apparatus

The overall concept of the PVD apparatus of PCT/EP2012/069156, published as WO/2013/045596 is to provide:
one or more vapour generators capable of forming a vapour from one or more condensed phase sources of material;
one or more plasma generators comprising one or more cathodes having one or more open-ended channels extending therethrough, the channels comprising one or more channel walls and having a length extending from one end of the channel to another end of the channel to define one or more spaces and capable of forming plasma within said one or more spaces;
   the one or more vapour generators and one or more plasma generators being arranged whereby in operation, vapour generated by the one or more vapour generators may traverse the one or more spaces through plasma formed by the one or more plasma generators. Some of the vapour will traverse the plasma as neutral species; and some will be ionized while traversing the plasma adding to the plasma. After traversing the plasma the vapour may impact a substrate to form a composition thereon.

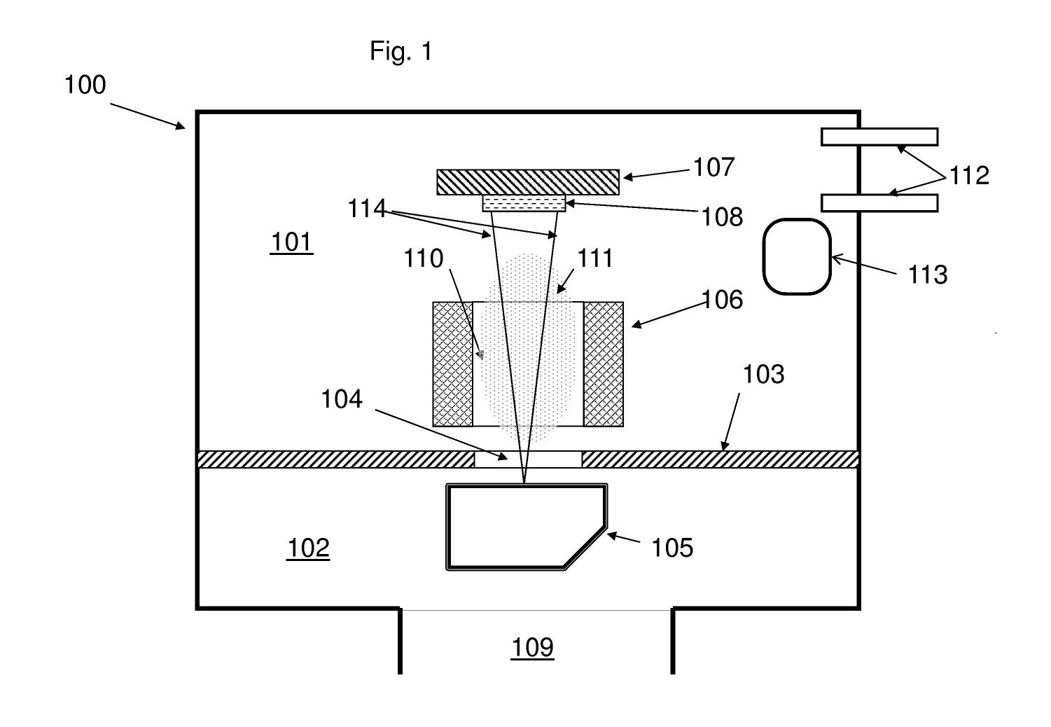

### Example PVD Apparatus of FIGS. 1 to 4

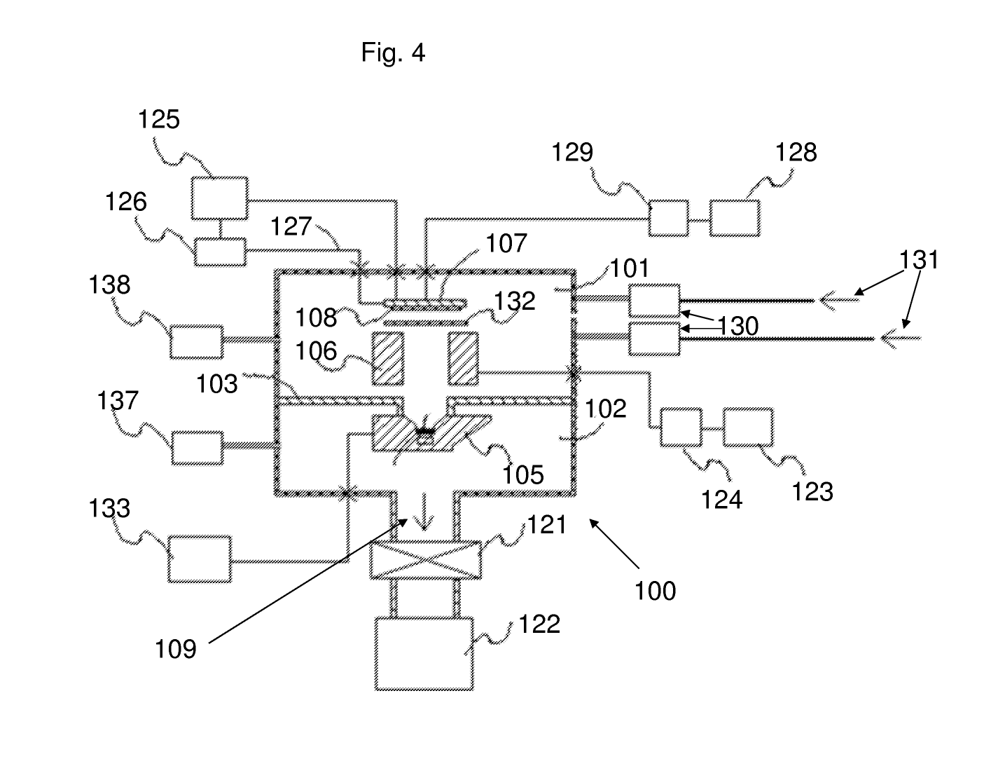

Apparatus 100 is shown in FIG. 1 and with associated equipment in FIG. 4, and consists of an upper chamber 101 and a lower chamber 102 separated by a partition 103 having an aperture 104 communicating between the upper chamber 101 and lower chamber 102. The upper chamber 101 and lower chamber 102 can be separated to permit access to the interior, although alternative means of access [for example doors or ports] can readily be envisaged by the person of ordinary skill in vacuum technology.

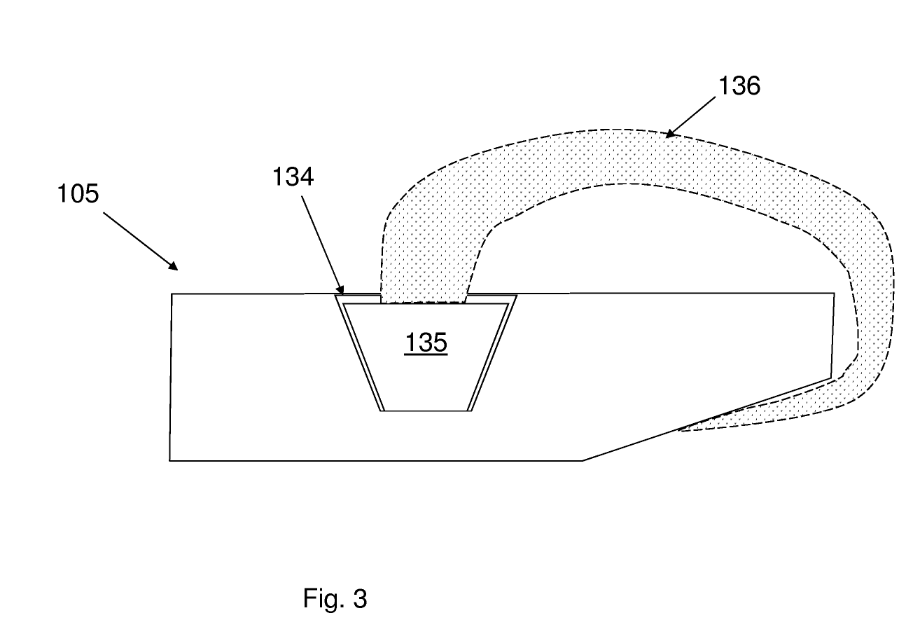

Beneath the aperture 104 is a vapour generator 105 (shown in more detail in FIG. 3).

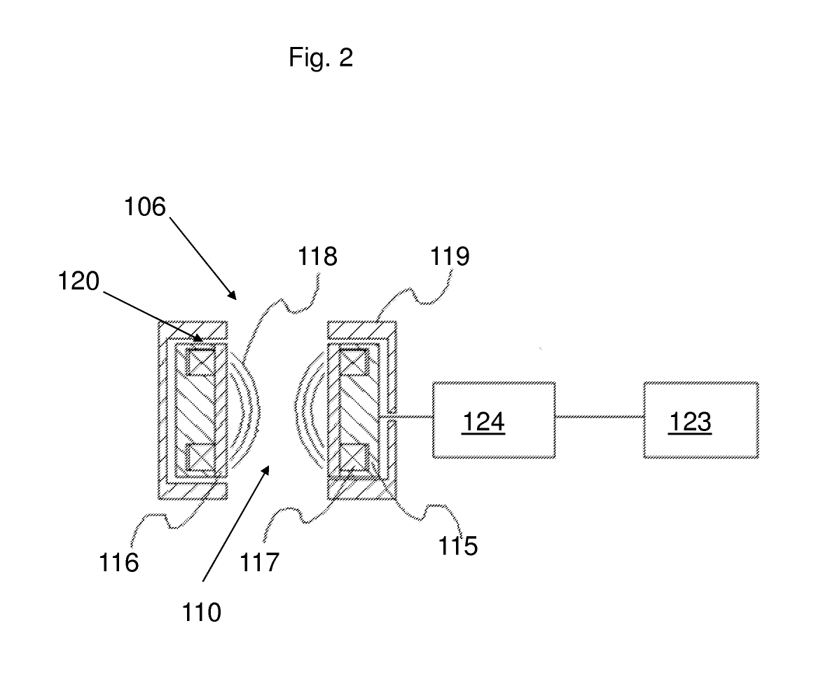

In the upper chamber 101 is a plasma generator 106 (a useful form of plasma generator 106 is shown in more detail in FIG. 2) and a substrate mount 107 to which a substrate 108 may be mounted.

Plasma generator 106 comprises a space 110 within which, in operation, a plasma 111 is generated which may extend outside the confines of the space 110. The plasma generator 106 shown is annular in form, but it can be readily appreciated that other arrangements [e.g. opposed plate cathodes, spiral cathodes—see Radio frequency hollow cathodes for the plasma processing technology, I. Bárdo\check{s}, Surface and Coatings Technology 86-87 (1996) 648-656] can be used to provide a space within which the plasma may be generated.

In WO2009/092097 reference is made to a concentric hollow cathode device in which an annular core of the hollow cathode functions as a sputtering target. The device of WO2009/092097 is not suitable for use in the present invention as it is closed at one end.

The plasma is generated from gas introduced into upper chamber 101 [for example through gas inlets 112]. An optional gas cleaner 113 may be provided within the chamber to reduce the content of oxygen and/or water vapour in the chamber. Dependent upon the gases used, the gas cleaner 113 may include a cold trap and/or an oxygen getter. Examples of cold traps include Meissner traps, in which liquid nitrogen is used to collect oxygen and/or water. [However Meissner traps are generally not useful when ammonia is a nitrogen source]. Examples of oxygen getters include, for example, a magnetron sputter source of a reactive metal which is used to getter oxygen and moisture from the process chamber. Suitable reactive metals include Ti, Zr, Hf, or Y.

The vapour generator 105 and plasma generator 106 are arranged such that when both are operating vapour 114 generated by the vapour generator 105 traverses the plasma 111.

FIG. 2 shows a useful form of plasma generator 106, although the invention is not limited to the specific geometry shown. A water cooled (water cooling is not shown) annular cathode backing 115 houses an annular cathode facing 116 which defines the space 110 within which plasma is generated. As shown, the space 110 is cylindrical in form having a length (from one open end of the channel to the other) and a diameter. The cathode facing 116 can be of any suitable material, but is preferably chosen to have elements in common with the material being made so that any material sputtered from the cathode facing 116 is less likely to contaminate the material being made. For example, when making MN, it can be useful for the cathode facing to be of aluminium, e.g. 6 nines pure Al.

Two rows of magnets 117 are housed between cathode backing 115 and cathode facing 116. One row of magnets has the north poles facing inward and the other row has the south poles facing inward. The resulting magnetic flux 118 is aligned parallel with the cathode facing 116 for a substantial part of the length of the space 110 [e.g. >50%, >60%, >70%, >80%, or >90% of the length]. A yoke [not shown] may join the ends of the magnets 117 remote the cathode facing 116 so that the magnets 117 form part of a magnetic circuit with the yoke and the magnetic flux 118 in the space 110. It will be evident that one or more electromagnets may provide the same effect.

Cathode housing 119 is electrically isolated from the cathode backing 115 and cathode facing 116 and acts as an anode with respect to the cathode backing 115 and cathode facing 116, serving to prevent plasma forming on the outside of cathode backing 115. Conveniently cathode housing 119 is separated from cathode backing 115 to form a so-called dark space 120. “Dark space” is a narrow space small in comparison with the mean free path of electrons at the operating pressure, resulting in no plasma discharge between the housing 119 and the cathode backing 115. The plasma is confined to only to the surface of cathode facing 116 so that there is no ionization of the gases: electrons from the cathode reach the cathode housing without exciting a discharge in the dark space. It is possible to dispense with the cathode housing and use the walls of the upper chamber 101 as an anode, but this would result in stray plasma and excessive generation of deposited material where it is not wanted, unless the walls of the chamber can be used for the dark space shield.

FIG. 3 shows a vapour generator 105 usable in the present invention. The vapour generator 105 may comprise an electron beam generator, operable to direct an electron beam at a condensed phase source of material, for example a first component of a composition to be deposited on substrate 108. The vapour generator comprises on its top face a depression 134 to receive a crucible 135. An electron gun (not shown) is situated on the underside of the vapour generator and magnets (not shown) are operable to bend an electron beam 136 from the electron gun to impact material held in the crucible 135. Such vapour generators are known, and a suitable apparatus is a Temescal Corporation Model SFIH-270-2.

FIG. 4 shows the apparatus of FIG. 1 with associated equipment. The lower chamber 102 has a conduit 109 connecting via a gate valve 121 to a vacuum pump 122 (for example, an Edwards Model 30). A cryogenic pump may be preferred.

To measure pressure in the system, pressure gauges 137 and 138 are connected respectively to the lower and upper chambers 102,101. Pressure gauges 137 and 138 may be of any type suitable for the pressures and gases to be experienced. Typically, for the pressure gauge 137 an ion gauge can be used as pressures of the order of 10⁻⁶ to 10⁻³ Torr are likely to be experienced (the gauge may be controlled, for example, by a Granville Phillips Model 270). For the pressure gauge 138 a baratron (for example MKS Model 125AA) may typically be used as the pressures experienced are likely to be higher than in the lower chamber. The invention is not limited to any particular pressure measurement method.

Such an arrangement in which the pressure in the lower chamber is lower than that in the upper chamber, has the advantage that electron beam sources work best at low pressure and maintaining a low pressure in the lower chamber prevents high voltage arcing from the filament to ground while allowing sufficient gas pressure in the upper chamber 101 to allow the hollow plasma generator to efficiently ionize nitrogen-containing gas.

A shutter can be mounted between the upper and lower chambers for selective operation if it is determined that the metal vapour is coating the surfaces of the hollow cathode with metal prior to the application of gases and plasma generation.

The cathode backing 115 (shown in FIG. 2) of the plasma generator 106 is attached to a voltage supply, which in the embodiment depicted is an RF generator 123 (for example a Dressler Model CESAR) attached through a matching network 124 (for example a Dressler Model CESAR).

Partition 103 may be of steel or like soft magnetic material, and optionally may be connected to cathode housing 119 (shown in FIG. 2), to provide magnetic shielding to inhibit interaction of the magnetic field of the plasma generator 106 with the magnetic field of the vapour generator 105; and more particularly to inhibit interaction of the magnetic field of the plasma generator 106 with the electron beam 136.

The substrate mount 107 is in the form of an electrically resistance heated chuck supplied with power from a power supply 125 (for example a Eurotherm SCR 40) controlled by a power controller 126 (for example, a Eurotherm Model 1226e) connected to a thermocouple 127 which measures the temperature of the substrate mount 107. Such an arrangement of heated substrate mount, power supply, and power supply controller enables the temperature of the substrate mount, and hence the substrate, to be maintained at a desired value.

Measurement of the temperature of the substrate surface [for example by pyrometry of the surface of the substrate 108] may provide greater control, particularly when the substrate is thick. The substrate 108 is held against the substrate mount 107 by three spring loaded pins [not shown] but any other suitable means may be used.

A second RF generator 128 (for example Dressler Model CESAR) is attached to the substrate mount 107 through a second matching network 129 (for example Dressler Model CESAR)

Mass flow controllers 130 (for example Unit Instruments Model UFC 1000) control the supply of gases 131 to gas inlets 112 (shown in FIG. 1).

A shutter 132 is provided between the plasma generator 106 and substrate mount 107. Contaminants and vapour are inhibited or prevented from deposition on the substrate 108 by the shutter 132. The shutter also serves to inhibit deposition from the substrate onto the hollow cathode during plasma etch cleaning of the substrate prior to deposition, and inhibit deposition from the hollow cathode onto the substrate while the hollow cathode plasma reaches equilibrium.

The shutter 132 may be provided with a periscope (not shown) for internal inspection of the apparatus as described below.

Vapour generator power supply 133 supplies power to the vapour generator 105.

### Typical Operation of the Apparatus of FIGS. 1 to 4

The apparatus can be operated in the following general steps, realizing that modifications can be made in the steps and procedure and still accomplish the purposes/features of the present invention. A substrate 108 may be mounted on substrate mount 107 and a condensed phase source of material [e.g. gallium or aluminium, alloys thereof, or other desired components] can be placed in crucible 135. The shutter 132 would be in place between the plasma generator 106 and substrate 108. The system would be pumped down to evacuate the upper and lower chambers 101,102. A typical pressure in the chambers at this stage would be about 10⁻⁶ Torr, though other pressures above and below this may be used.

Once down to pressure, and in either order the following can be done:—
Power supply 125 would be turned on to supply heat to the substrate mount 107 and hence to the substrate 108 to get it to an appropriate temperature for the desired product. For instance, for deposition of crystalline MN 850° C. can be used, although other temperatures can be used, and the appropriate temperatures may depend on the substrate and the deposited material.
RF generator 128 would be turned on to supply RF to the substrate mount 107 and hence to the substrate 108 (resulting in a DC bias, as is conventionally known) and argon would be introduced into the chamber through one or more of the gas inlets 112. The Ar (or other inert gas) pressure in the upper chamber may be 10⁻³ to 5×10⁻³ Torr and the applied RF power may be ˜50-100 watts resulting in a substrate bias of 250-300 volts although voltage in the range 300-400V may be used.
   This serves to get the substrate 108 to a suitable deposition temperature, and to clean the substrate by Ar bombardment. The bombardment can typically proceed for 5 to 10 minutes. Inert gases other than argon [e.g. Ne, Kr or Xe] may be used in the cleaning step as may mixtures of inert gases.

The argon supply would then be turned off and the RF generator 128 turned off.

Vapour generator power supply 133 would then be turned on and the electron beam current increased to start heating of the condensed phase source of material. Typically the aim is to increase the condensed phase source of material to a temperature at which it is molten, and has a usefully high vapour pressure for deposition, without splashing the material through excessive boiling or outgassing of impurities or trapped gases. It can be useful to be able to observe the condensed phase source of material to ensure appropriate heating. For example, if the vapour generator is an electron beam device [for example as shown in FIG. 3], it can be useful to observe the incidence of the electron beam on the condensed phase source of material to ensure proper alignment. A periscope in the shutter or situated in the lower chamber 102 may be used for this purpose.

During this heat up process, surface contaminants on the condensed phase source of material may be vaporized. Contaminants and vapour are inhibited or prevented from deposition on the substrate 108 by the shutter 132.

Once the condensed phase source of material is molten, contaminants produced on the condensed phase source of material are either vaporized or sink or float to the edges of the molten material.

Argon, or any other inert gas such as Ne, Kr, Xe or others, can be injected over the material to be evaporated in the E-beam. The argon or other inert gas reduces the possibility of the reactant gas reacting with the molten surface material. Typically, without this argon blanket over the molten metal surface, MN forms on the surface preventing the Al vapour from leaving the molten surface, and the MN on the surface is sputtered by the E-beam causing particles of Al+MN to be ejected from the E-beam source onto the substrate. These same procedures can be implemented with other source materials as described herein to protect the source material during melting and vaporizing.

One or more reaction gases [e.g. for nitride production N₂, NH₃, N₂H₂, or other nitrogen hydrides or nitrogen containing compounds; for oxide production, gases containing oxygen; for fluoride production fluorine containing gases; for mixed products [e.g. oxynitrides] a single gas comprising the required elements or a mixture of gases may be used] may be introduced into the upper chamber through one or more of the gas inlets 112. Some argon may also be introduced into the reaction chamber to assist in bombardment of the substrate 108, as this may improve the properties of the deposited material. A typical pressure in the upper chamber 101 would be about 10⁻⁴ to 10⁻² Torr [for example 1×10⁻³ to 5×10⁻³ Torr; 1×10⁻³ to 2×10⁻³ Torr; or 3×10⁻³ to 5×10⁻³ Torr]. The pressure experienced in the lower chamber 102 would normally be less, for example about half or between a fifth and a tenth that for the upper chamber 101. For example, the pressure might be in the range 1×10⁻³ to 2×10⁻³ Torr in the upper chamber and 3×10 to 5×10⁻⁴ Torr in the lower chamber, though other pressures and pressure differences between the two chambers can be used.

The operating pressure of the vapour generator can be less than 5×10⁻⁴ Torr and the operating temperature of the plasma generator can be 1 to 2×10⁻³ Torr with an evacuation rate of >1000 l/min. A reactant gas feed rate (if used) can be 2-5 sccm (or above or below this range), and an inert gas feed rate to blanket the melt (source material) can for example be 10 sccm or less. These are examples and other amounts can be used for any of these ranges.

Once the upper chamber 101 is at pressure, RF generator 128 can be turned on to supply 15-25 watts resulting in an RF bias of 80-150 volts to the substrate mount 107 and hence the substrate 108; and RF generator 123 turned on to supply RF to the cathode of the plasma generator 106. A typical bias for RF generator 123 is ˜350 volts.

The RF applied to the vapour generator initiates a plasma discharge 111 in the space 110 resulting in ionization of the gases present, and the discharge may extend out of the confines of the space 110 towards either or both of the vapour generator 105 or substrate 108.

Vapour 114 from the vapour generator 105 can react with the ionized gases in plasma 111. For instance, in the case of Al as the source material and nitrogen as reactant gas, MN starts to form on the shutter 132. On removal of shutter 132 the vapour 114 and/or plasma 111 can reach the substrate 108 and commence deposition on the substrate. Application of RF bias to the substrate results in localised plasma generation and assists in bombarding the surface of the depositing material. For amorphous deposition it is preferable that no bias is applied to the substrate.

The rate of deposition can be measured [for example by using a deposition monitor, for example an Inficon Model U200]. Deposition temperatures have been used from 100-1100° C. depending on the substrate material and deposition rates have been from 0.1 to 60 μm per hour, typically 40-60 μm per hour, although the invention is not limited to these temperatures or deposition rates.

Once the deposited material has reached a required thickness or depth the following may be done:—
the shutter 132 is closed
the RF supplies to the substrate mount 107 and plasma generator 106 are turned off
all gases are turned off
the heater to the substrate mount 107 is turned off
the power to the vapour generator is turned off [this is best done slowly to avoid voids forming in the solidifying material]
nitrogen is injected into the vacuum chamber until it reaches atmospheric pressure
the vacuum chamber is opened when the substrate temperature is less than 500° C.
the substrate 108 is removed [optionally after cooling for an appropriate time]

The above describes a procedure with the apparatus shown. It will be evident that the apparatus can be used in different ways depending upon the nature of the material to be deposited. For example, the constitution of the gases may vary during the process, and the constitution of the vapour may be varied, for example by switching between alternative vapour sources. Control of the process can be automated, for example by computer control such as using National Instruments LabVIEW.

### Specific Examples of Deposition Process

### Comparative Example 1

The present comparative example is from PCT/EP2012/069156 published as WO/2013/045596.

Aluminium nitride was made by placing pure Al (5 nines purity) in the crucible of the apparatus of FIGS. 1 to 4. A silicon substrate was secured to the substrate mount. The substrate 108, which can be Si or other material, was mounted to the substrate mount 107 and heated to typically 850° C.

[Generally, and not limited to or by this example, the substrate is heated to a temperature below the melting or deposition temperature of the substrate material, which can usefully be well below the melting temperature of the substrate material to avoid warping if the coefficients of expansion for the substrate and film are significantly different, such as more than 20% or more than 30%.

Generally, typical substrate temperatures are anywhere from 250-1000° C. depending on the substrate material and the required crystallinity of the deposited material [e.g. AlN]. Typical temperatures for deposition of AlN on various substrates include but are not limited to 300° C.±50° C. for deposition on copper and aluminum and 800° C.±50° C. for deposition on Si, SiC, and aluminium oxide (sapphire)

The present invention is not limited to these temperature ranges or materials and further examples of suitable materials are given below.]

NH₃, N₂ and Ar gases were introduced to the upper chamber 101 by gas inlets 112 (typical proportions were 50% NH₃, 35% N₂ and 15% Ar). The pressure in the upper chamber 101 was observed to be approximately 3-5×10⁻³ Torr, and in the lower chamber 102 approximately 3-5×10⁻⁴ Torr although pressures in the upper chamber 101 of approximately 1-5×10⁻³ Torr, and in the lower chamber of approximately 3-7×10⁻⁴ Torr have been observed.

Growth rate shown was >40 μm/hour and on occasion >80 μm/hour and XRD of the deposited material showed hexagonal AlN.

Following these procedures, AlN has been successfully deposited on Si, Al, sapphire, Mo, W, Nb, Ta, SiC, diamond, Cu, and Ta with no peeling or cracking in the machine. The deposited AlN films were transparent.

### Comparative Example 2

A metal or graphite or diamond sheet, or a crucible was attached to a substrate mount above the electron beam hearth in the same vacuum chamber. The chuck was face down towards the electron beam hearth. The vacuum chamber was pumped down, typically <5×10⁻⁶ Torr, and backfilled with Ar to 3×10⁻³ Torr. An RF generator, with any range, for example 13.56 M Hz, was attached to the substrate mount and turned on, typically at 100 W, for 10 minutes to clean the substrate. The RF generator was turned off and the vacuum chamber again pumped down to <5×10⁻⁶ Torr. The substrate mount temperature was increased to 800° C. The electron beam was turned on to melt the Al and bring the deposition rate to ˜0.3 nm/sec. This rate can be increased to the rates described herein by increasing the power of the electron beam. Ar was turned on at ˜3 sccm and NH₃ was turned on at ˜10 sccm resulting in a vacuum pressure of ˜6×10⁻⁴ Torr as measured in the lower chamber.

An RF generator, attached to the hollow cathode was turned on which created a plasma and ionized the N₂. The RF generator attached to the substrate mount was also turned on which created a self bias on the substrate, typically 120-140 volts. This bias caused the Ar ions to bombard the AlN being deposited resulting in a very dense, crystalline film.

A shutter between the electron beam gun and the crucible was then opened. The shutter was opened typically for 15 minutes, resulting in ˜15 μm of AlN deposition. The shutter was closed and the electron beam turned off, the RF generators were turned off and gases turned off. The chuck heater was turned off. When the chuck reached 500° C., the vacuum chamber was back filled with N₂ to atmospheric pressure. The vacuum chamber was opened and the metal or graphite or diamond sheet, or crucible was removed.

The AlN coatings produced had excellent adhesion to metals, graphite and diamond such that the coated substrates were heat cycled to 1100° C. with no cracking or peeling of the AlN. A graphite substrate with a 5 μm AlN coating that was heat cycled to 1100° C. showed no degradation of the AlN film. A 15 μm film on a diamond coated silicon substrate that was heated to 1100° C. showed no degradation of the AlN film. Such AlN coated, high thermal conductivity materials can be used in thermal management.

Following essentially the same procedures,
AlN has been deposited up to 15 μm thick onto Cu with no cracking or peeling of the AlN.
AlN has been deposited up to 15 μm thick onto diamond with no cracking or peeling of the AlN.
AlN has been deposited at thicknesses ranging from 100 nm to 150 μm onto silicon wafers with no cracking or peeling.

Greater thicknesses are readily achievable.

### Example 1

Using the apparatus and method of comparative example 1 a 5 μm thick layer of AlN was coated onto a 0.127 mm (0.005 inch) thick sheet of Ta and the coated Ta sheet was then rolled into a tube 9.5 mm (0.375 inches) in diameter. No peeling or cracking of the AlN was observed.

Such a material is considered very flexible. As stated above, in this specification, flexible is to be taken as meaning capable of being flexed or bent without breaking and in particular capable of being bent on to a former with a radius of less than 5 metres without breaking. With appropriate choice of materials and thicknesses, the substrate, or both the substrate and the coated substrate can be flexed or bent without breaking when bent on to a former with a radius of less than 1 metre, or less than 50 cm, or less than 20 cm, or less than 10 cm, or less than 5 cm, or indeed, as in Example 1, less than 1 cm.

With the invention, an intermediate region can be present between the deposited material and the substrate. This intermediate region may have a different composition or structure than the deposited material or the substrate itself. The intermediate region may be a reaction product of one or more components that form the deposited material and one or more components that form the substrate.

This intermediate region can occur through reaction in the initial stages of deposition, with the remaining thickness of the deposited material forming on top; or it may occur through subsequent reaction of deposited material with the substrate; or indeed it may be a separately applied layer, which optionally may have a distinct difference in chemical composition from either substrate or deposited material.

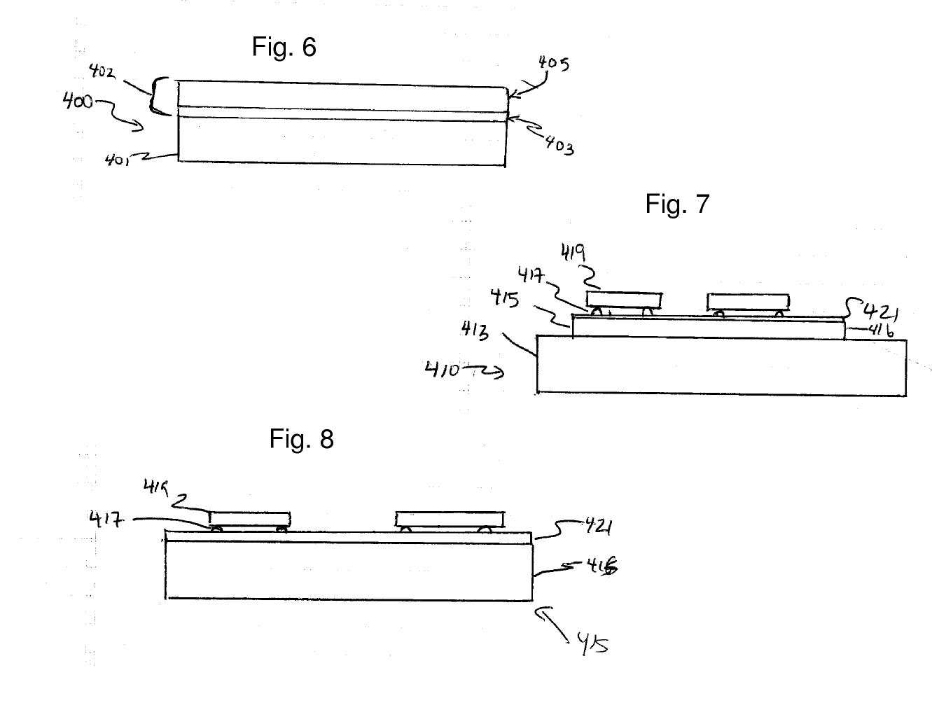

FIG. 6 shows an example of a layered design. In FIG. 6 (not to scale), a laminate 400 is shown. A substrate 401 can have a layer 402 adhered to a surface of the substrate. The layer 402 can have an intermediate region 403 sandwiched between a deposited layer 405 and the substrate 401. Intermediate region 403, may have a different composition or chemical make-up than the deposited layer 405. The intermediate region 403 can be a reaction product of one or more components that form the film 405 and one of more components that form the substrate 401.

As an example, without limiting the present invention, substrate 401 can be any flexible material, for example copper and film region 405 can be MN, wherein intermediate region 403 would comprise a reaction product of aluminum, nitrogen, and/or aluminum nitride with one or more components that comprise the substrate.

The present invention contemplates both intermediate layers formed through reaction with the substrate, and deliberately formed intermediate layers. Such laminates can be used as heat sinks for thermal management.

As an example, aluminium nitride as a film that is deposited on a flexible substrate, such as a metal, ceramic, glass or even plastic flexible substrate can provide excellent thermal management properties due to the properties of aluminium nitride. For instance, the film can have a thermal conductivity of 210 W/mK to 319 W/mK, such as from 210 to 275 W/mK or 210 to 250 W/mK.

The aluminum nitride located on the substrate can have one or more of the following additional properties:

| Flexural Strength | MPa (lb/in² × 10³) | 320 | (46.4) |
|---|---|---|---|
| Elastic Modulus | GPa (lb/in² × 10³) | 330 | (47.9) |
| Poisson's Ratio | — | 0.24 | |
| Compressive Strength | MPa (lb/in² × 10³) | 2100 | (304.6) |
| Hardness | Kg/mm² | 1100 | |
| Knoop hardness | 100 gm load, HK 0.1, 10 | 1412 ± 143 | |
| Fracture Toughness K_{IC} | MPa · m^{1/2} | 2.6 | |
| Coefficient of Thermal | 10⁻⁶/° C. (10⁻⁶/° F.) | 4.5 | (2.5) |
| Expansion | | | |
| Specific Heat | J/Kg · ° K (Btu/lb · ° F.) | 740 | (0.18) |

| | | |
|---|---|---|
| Dielectric Constant | @ 1 MHz | 9 |
| Volume Resistivity | ohm · cm | >10¹⁴ |

Thermal management may be for any device, for example an electronic device, like a CPU, light radiation emitting device (e.g. LED), phone, smart device, and the like. For instance, the laminate 400 may comprise a layer of material adhered to a substrate, with either or both the layer and substrate being of high thermal conductivity material.

For example, a material such as aluminium nitride adhered to a metal substrate like copper, can be used as a heat sink in lieu of, for instance, a printed circuit (PC) board or mount (or sub mount) which typically are made from a polymer material or resin and are not good conductors of heat. Other substrates with high thermal conductivity include, for example and without limitation, other metals, graphite, and diamond.

With the present invention, one or more chips, such as integrated circuits (ICs) or computer chips, can be connected to the laminate through interconnects or bumps, and, due to the dielectric nature of the film (for instance, aluminium nitride), the interconnects or bumps can be made out of metal without any need for separate insulation layers.

As an alternative, the laminate heat sink of the present invention can be located on a mount or PC board or be the mount or PC board itself.

As an example, the laminate heat sink of the present invention can be a heat sink for a light-emitting diode device, wherein a die(s) is located on the heat sink and, due to the dielectric nature of the film used for the laminate heat sink of the present invention, no separate insulator is needed between the die and the heat sink.

FIGS. 7 and 8 show examples of these features. As shown in FIG. 7, an assembly 410 comprising a mount or PC board 413 with mounted IC chips 419 is shown.

The mount or PC board 413 can have the laminate of the present invention 415 located on top and adhered to the mount or PC board 413. The laminate 415 can comprise a substrate 416, which can be any of the substrates identified in the present invention, but for this embodiment, the substrate preferably is a good thermal conducting substrate such as copper.

Located on the substrate is a layer 421, for instance, of aluminium nitride or other material that has a good thermal conductivity. The bumps 417 from the IC chip or other electronic part can be connected to the layer 421 for purposes of securing the chip 419 and providing good thermal connectivity.

In an alternative example, FIG. 8 shows where the laminate 415 of the present invention, which has a substrate 416 and a thermal conducting layer 421, can serve as the mount or PC board itself. One or more IC chips 419 can be attached to layer 421 by bumps 417.

Although bumps are shown in FIGS. 7 and 8, other means of providing good thermal conductivity between the IC chips 419 and layer 421 are contemplated, for example metallic or other high thermal conductivity layers.

### Apparatus Modifications

### Alternative Arrangements

In the example apparatus of FIGS. 1 to 4, a single vapour generator, and a single plasma generator having a single space are described, but the invention is not so limited. For example:—
a single vapour generator may feed a plasma generator having more than one space
a single vapour generator may feed more than one plasma generator having one or more spaces
more than one vapour generator may feed a single plasma generator having one or more spaces
more than one vapour generator may feed more than one plasma generator having one or more spaces.

In the example apparatus of FIGS. 1 to 4, a single substrate is shown mounted on a single and fixed substrate mount but the invention is not so limited. The invention contemplates:—
multiple substrates being mounted on a single substrate mount;
movable substrate mounts [for example mounts that may be rotated or slid]
movable substrate mounts and air locks to permit removal of the substrate from the apparatus while still under vacuum.

Much expertise in the handling of substrates has been developed in the field of semiconductor processing and the invention contemplates the use of any and all known technology that can be usefully applied to the present invention.

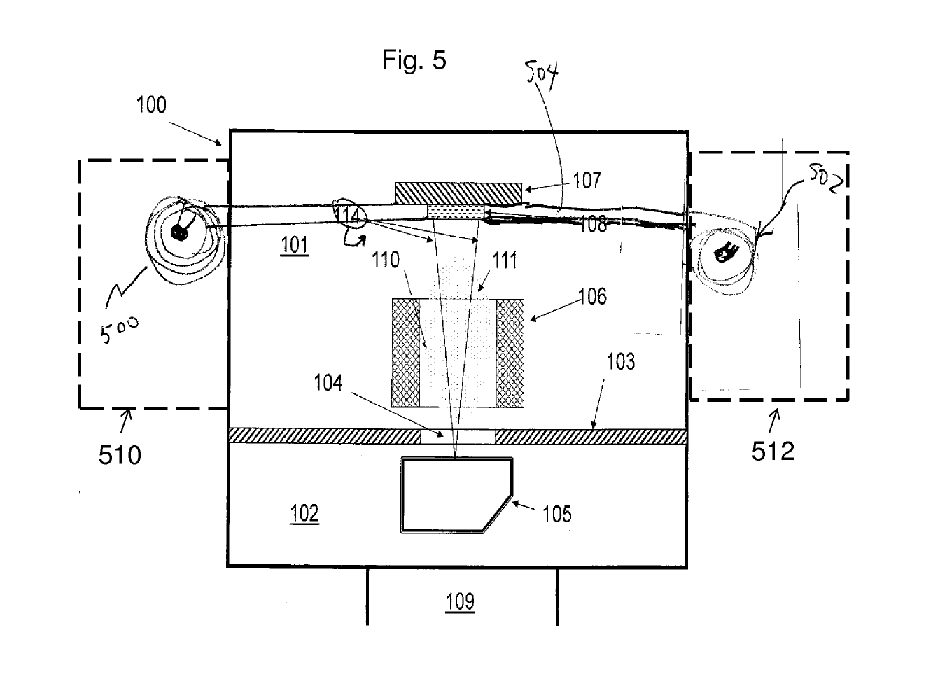

As the present invention relates to deposition on flexible substrates, several modifications may be applied. FIG. 5 shows an apparatus in accordance with one aspect of the present invention which involves forming a film on a roll of flexible substrate for a continuous or semi-continuous operation.

As shown in FIG. 5, which is similar to FIG. 1, a roll of flexible substrate 500, such as a roll of copper, can be fed into the apparatus 100 and will serve as the substrate 108, whereupon a film can be deposited on the substrate to form a coated substrate or laminate 504, which then can be optionally rewound into a laminate roll 502. The substrate can be incrementally fed or fed at a constant rate to match the desired deposition rate and desired thickness of film forming on the substrate 108. The apparatus of FIG. 5 may include any or all of the features of the apparatus of FIG. 1 but some further features may be required.

The apparatus of FIG. 5 as described above would require some form of vacuum gate to prevent access of air to the chamber 101. In an alternative construction both roll 500 and laminate roll 502 may be housed inside the upper chamber 101 or may be housed in evacuable chambers 510 and 512 shown as dashed lines in FIG. 5, with airlocks operable to close off evacuable chambers 510 and 512 to permit loading and unloading of roll 500 and laminate roll 502 respectively.

Optionally a separate heating section is provided with an RF generator to clean the roll [or the flexible substrate as it unrolls] prior to any deposition.

In the case of AlN coating, it is suspected, although the applicant does not wish to bound by this hypothesis, that the AlN is at least partially oxidized in the heat treatment, perhaps to form, in part at least, an aluminium oxynitride layer. The present invention contemplates a process in which an applied nitride coating, particularly although not exclusively an AlN coating, is further modified through exposure at elevated temperature to an oxygen containing material. The material may be an oxygen containing gas or may result from contact with a liquid or solid oxygen-containing reactant.

In the case of AlN coating, the invention further contemplates oxidation being part of the process of deposition, for example by introducing oxygen-containing gases [e.g O₂, H₂O or nitrogen oxide] during the final stages of deposition of the AlN.

The invention still further contemplates complete oxidation of the AlN to provide an aluminium oxynitride throughout the coating.

Reducing surface roughness before coating may assist in reducing defects in the coating.

The process described above may be used generally to produce laminated articles comprising one or more deposited layers on a flexible substrate. Although in the examples metals have been mentioned as potential substrates for deposition of layers, the invention has wider applicability and encompasses deposition on any flexible substrate capable of receiving an adherent deposit without material damage to the substrate.

Typically, the substrate may have a melting or decomposition temperature of over 200° C., or over 300° C. or over 400° C. Substrates may include, for example, a metal, glass, ceramic, glass ceramic, carbon based materials for example graphene, functionalised graphene, exfoliated graphite, or composites comprising carbon based materials, or polymer, as long as the melting temperature of the substrate is high enough to resist damage in the process of deposition. The substrate may be crystalline, partially crystalline, or amorphous. If a polymer is used it may be thermoset or thermoplastic although thermoset polymers may be better in resisting damage in processing.

By adherent deposit is meant a deposit that exhibits no cracking or peeling in ordinary use of the laminated article. This can include no cracking or peeling occurring even after the substrate with the adhered deposit has been exposed to high temperatures, such as temperatures that are within 20% of the melting temperature of the substrate or layer (whichever is the lower) even after return to a lower temperature [e.g. 25° C.]. Adherence can be tested by other methods [e.g. cycling between a lower and a higher temperature].

The deposited layers adhered to the substrate(s), can have low oxygen contents when oxides are not intended. For instance, a metal or metal nitride or other non-oxygen containing layer can be deposited on a substrate(s), wherein the layer has a low oxygen content. The oxygen content for such layers can be under 300 ppm, such as from about 1 ppm to 299 ppm, or 3 ppm to 100 ppm, or 1 ppm to 100 ppm, or 1 ppm to 10 ppm, and the like. Due to the processes of the present invention, other impurities, such as gaseous impurities and/or metal impurities, can be very low. For instance, if using a source material that is vaporized that has a very high purity, such as 99.999% or 99.9999% purity, all other impurities (gaseous and/or metal or total other impurities) in the film can be below 10 ppm, can be below 5 ppm, can be about 1 ppm or 1 ppm, such as from 1 ppm to 5 ppm.

With the present invention, the layer deposited on a substrate can have excellent coating uniformity, for example as low as ±5% throughout the entire deposited surface of the substrate. With the present invention, the deposited layer on the substrate can have no observable voids or pin holes at a magnification of 300× or 500×. The deposited layer adhered to the substrate can have any desired thickness, such as from about 0.1 micron to 2 mm or more, such as 0.1 micron to 2 mm, 0.1 micron to 1 mm, 10 microns to 500 microns, 10 microns to 100 microns, and the like.

The substrate, prior to having a film deposited on it, can be pre-treated with any conventional techniques, such as cleaning the surface, acid treating, polishing (e.g., electro-polishing) the surface, and the like. These various cleaning or polishing steps can be done using any conventional technique associated with a substrate material. Similarly, after the film is deposited on the substrate, the laminate, which can have any shape, can be subjected to any number of post-treatments, such as, but not limited to, cleaning treatments, heat treatments at any various temperatures or pressures, passivated, or otherwise treated with liquids or gases (for example nitrogen and/or oxygen, halogen-containing gases, and/or air at optional room and/or elevated high temperatures, and/or at optional elevated pressures).

It should be noted that the method provides for deposition on a flexible substrate, however thick coatings may be applied and the invention is not limited to flexible coated articles, although flexible coated articles may be preferred for the breadth of their utility.

Material made by the processes described above may have one or more layers deposited thereon of different composition to said material.

Material made by the processes described above may be used as is or further processed to form, one or more components in a device comprising one or more: electronic components; opto-electronic components; electro-acoustic components; MEMS components; and/or spintronic components.

### Electrode Materials

The applicant has realised that vapour deposition provides a route to manufacture of novel electrode materials for use in electrochemical devices, for example batteries. In the following, reference is made to manufacture of anodes for lithium ion batteries, but the invention is not limited thereto.

Lithium-ion batteries of various sorts have achieved widespread use in a number of applications. Whilst most regularly seen in electronic products such as mobile phones, laptops, cameras and other handheld devices, they have also seen use in power tools and are increasingly used in more demanding applications such as in vehicles ranging from electric cars and planes to tugboats and yachts.

There are many desirable aspects to the use of lithium-ion batteries in more varied applications, not least the environmental impact; if electric vehicles or hybrid electric vehicles utilising lithium-ion batteries are used in preference to vehicles powered by fossil fuels then harmful atmospheric emissions causing air pollution, smog, and climate change can be limited. However, if such batteries are to see widespread use they must deliver power efficiently whilst keeping the cost of manufacturing them low. There is therefore a need for methods of enhancing the properties of a lithium-ion battery which may be put into effect using low-cost materials and simple techniques which can be easily applied in industry. Such improvements must also take into consideration safety concerns, both in terms of the design of the battery and any risks posed to users by the materials used to make the battery.

Bearing in mind these considerations, a range of lithium-ion based batteries have been produced in which the negative electrode in discharge [referred to in the following as the anode], comprises carbon, and in particular graphite particles, since graphitic species are both safe, have a high capacity for the storage of lithium ions, and are conductive. Typically, anodes are made from a mixture of carbon materials with an electrically conductive additive [typically carbon black] and a binder.

While graphite is an established material for anode manufacture, there are a range of other materials that have been proposed as being potentially useful as having higher capacity for lithium than graphite. The most popular for study currently appear to be Si, Sn, Sb, Ge and Al, but materials that have been investigated include metals and alloys that alloy with lithium, or compounds that form further compounds with lithium.

However a problem with such materials is that they show much greater expansion and contraction on absorption and desorption of lithium, and this progressively leads to mechanical breakdown of the material and hence reduced charge-discharge efficiency.

It has been proposed to apply an active material layer, comprising an active material containing a metal capable of forming an alloy with lithium and a binder resin, to copper foil [WO2011074439].

The applicants believe that application of active materials to a current collector using vapour deposition will enable the controllable application of said materials to provide an adherent coating of the active materials, which is likely to provide a low electrical resistance (impedance) within the electrode.

Accordingly the present invention further provides a laminate for use as an electrode for a battery, the laminate including an electrically conductive layer capable of acting as a current collector, and one or more layers including at least one active layer which includes one or more solid phases active to absorb and desorb a charge carrying element in operation of such a battery, characterized in that said at least one active layer is an adherent layer formed by vapour deposition. Absorption and desorption may be by physical absorption/desorption or by means of temporary alloy or compound formation.

The one or more solid phases may be active to absorb and desorb lithium as the charge carrying element. Absorption and desorption may be by physical absorption/desorption or by means of temporary alloy or compound formation.

Physical absorption may include adsorption onto a surface, absorption into a material, intercalation into interstices in material or a combination of any of these processes, which are sometimes called by the name sorption. Desorption is the reverse process in which the charge carrying element is released from where it has been absorbed. Temporary alloy or compound formation includes processes such as ion exchange and may include intercalation into interstices in a material to produce an alloy or compound.

The one or more solid phases may include one or more elements, alloys or compounds which can form alloys or compounds with lithium.

The one or more solid phases may include in elemental, alloy, or compound form, one or more of the elements B, Mg, Al, Si, Zn, Ga, Ge, As, Se, Pd, Ag, Cd, In, Sn, Sb, Te, Pt, Au, Hg, Tl, Pb, Bi.

The one or more solid phases may include an alloy of one or more of said elements with one or more other alloying elements. The one or more other alloying elements may include at least one element forming part of the electrically conductive layer.

For example, the electrically conductive layer may include copper and the one or more solid phases may include the alloy Cu6Sn5.

Alloys have potential advantages, in that the most promising elements in terms of capacity for lithium absorption/desorption [e.g. Si, Sn, Sb, Ge, Al] can have a relatively low electrical conductivity and are liable to mechanical damage in expansion/contraction.

By providing an alloy with a more electrically conductive and/or ductile element the electrical conductivity may be increased and/or resistance to mechanical damage may be reduced. Elements that are both more electrically conductive and ductile are preferred.

The one or more solid phases may include one or more alloys including at least one element selected from the group of Si, Sn, Sb, Ge, and Al, with at least one element selected from the group B, Mg, Zn, Ga, As, Se, Pd, Ag, Cd, In, Te, Pt, Au, Hg, Tl, Pb, Bi.

The one or more solid phases may include one or more alloys including at least one element selected from the group of Si, Sn, Sb, Ge, and Al, with at least one element selected from the group B, Cr, Nb, Cu, Zr, Ag, Ni, Zn, Fe, Co, Mn, Sb, Zn, Ca, Mg, V, Ti, In, Al, Ge

The one or more other alloying elements may comprise at least one element forming part of the electrically conductive layer. For example, where the electrically conductive layer comprises copper, the one or more solid phases may comprise the alloy Cu6Sn5 or any other alloy capable of alloying with lithium.

The active layer may be discontinuous, forming ridges and islands with gaps between that may be filled with other material or left empty to receive electrolyte.

The electrically conductive layer may itself have some capacity to absorb or desorb a charge carrying element in operation of such a battery and may comprise a laminate of a first electrically conductive layer and at least one second electrically conductive layer.

One or more of the first electrically conductive layer and at least one second electrically conductive layer may be capable of absorbing and desorbing a charge carrying element in operation of such a battery. The one or more layers capable of absorbing and desorbing a charge carrying element in operation of such a battery may comprise one or more carbon anode materials capable of absorption/desorption of lithium.

Further, the electrically conductive layer may comprise a laminate of one or more conductive layers with non-conductive layers. For example the electrically conductive layer may comprise a laminate of one or more conductive layers on a non-conductive or insulating carrier and may be, for example, a metallized plastic.

### Example 2

Using the apparatus of FIGS. 1-4, 3 μm thick layers of silicon were coated onto 100 μm and 13 μm thick copper foils to produce laminated structures comprising an adherent silicon coating on copper. The silicon warped the copper foil because of the differences in the coefficient of thermal expansion. However, the coated copper foils could be easily pressed flat without the silicon cracking or peeling.

This ease of flattening indicates that the coated copper foils will tolerate expansion and contraction with lithium absorption and desorption by the silicon.

Although in this example direct lamination of the active layer [silicon] to the electrically conductive layer [copper] is shown, it will be apparent that intermediate layers may be provided to give, for example, a gradation of properties. For example an intermediate layer of an alloy may be provided. Other materials that may be included as intermediate layers include, for example, carbon and/or graphite materials which may be capable of absorbing and desorbing lithium.

### Further Processing of Laminates

Having formed the laminate of an electrically conductive layer and one or more layers comprising at least one active layer it may be used as is, as an electrode in a battery; or it may be further processed before use in a battery. For example the laminate may be treated by one or more of the following processes, not necessarily in the order presented:—
the laminate may be cut to size;
a surface texture may be applied to the active layer;
the active layer may be chemically treated;
the laminate may be heat treated;
an additional layer may be applied using the same process except with a dissimilar element or alloy, to improve certain characteristics of the active layer, for example to reduce electrical impedance and/or to reduce the mechanical damage on cycling;
an additional layer may be applied by an alternative process to improve certain characteristics of the active layer, for example a carbon layer applied by Chemical Vapour Deposition (CVD) may be applied to reduce electrical impedance and/or to reduce the mechanical damage on cycling;
a physical or chemical treatment with a lithium containing material [for example SLMP® stabilised lithium metal powder from FMC Lithium] may be made in order in increase the first cycle efficiency of a battery made from the anode.

A surface texture may be provided to give stress relieving features to the layer and thereby accommodate expansion of the active layer. For example by dividing the active layer into ridges or islands with gaps between that may be filled with other material or left empty to receive electrolyte. A suitable process is disclosed in WO2004/042851 but other processes may be used.

Chemical treatment may comprise incorporation of dopants or other materials into the active layer.

Heat treatment may comprise annealing steps to relieve stresses caused in manufacture.

### General Comments

It should be noted that the above description is for the purpose of exemplification, and the present invention is not limited thereto.

The present invention can include any combination of these various features or embodiments above and/or below as set forth in sentences and/or paragraphs. Any combination of disclosed features herein is considered part of the present invention and no limitation is intended with respect to combinable features.

To the extent permissible under national law the entire contents of all references cited in this disclosure are incorporated herein in their entireties, by reference. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present description and examples be considered as exemplary only.

1. A method of manufacturing an article comprising at least one adherent coating on a flexible substrate, the method comprising the step of forming an ion beam and bombarding at least one flexible substrate with ions from the ion beam to form said adherent coating on the flexible substrate in which the ion beam is generated by an ion beam generator comprising:
a) a first chamber housing one or more vapour generators capable of forming a vapour from one or more condensed phase sources of material;
b) a second chamber adjacent the first chamber housing one or more plasma generators comprising
one or more hollow cathodes having one or more open-ended channels extending therethrough, the channels comprising one or more channel walls and having a length extending from one end of the channel to another end of the channel to define one or more spaces
and capable of forming plasma within said one or more spaces;
c) one or more apertures between the first and second chambers arranged to permit vapour generated in the first chamber to enter the second chamber
the one or more vapour generators and one or more plasma generators being arranged whereby in operation, vapour generated in the first chamber by the one or more vapour generators may traverse the one or more spaces through plasma formed in the second chamber by the one or more plasma generators.

2. A method as claimed in claim 1, wherein the vapour generator is capable of evaporative formation of a vapour from one or more condensed phase sources of material;

3. A method as claimed in claim 2, wherein the vapour generator comprises at least one electron beam generator, operable to direct an electron beam at the one or more condensed phase sources of material.

4. A method as claimed in claim 3, wherein the at least one electron beam generator is operable to magnetically bend electrons from the electron beam generator to the one or more condensed phase sources of material.

5. A method as claimed in any one of claim 1, wherein one or more of the one or more plasma generators further comprises one or more housings spaced from and electrically insulated from the one or more cathodes.

6. A method as claimed in any one of claim 1, wherein one or more of the one or more plasma generators further comprises a source for a magnetic field configured to lie substantially parallel to the one or more channel walls for a substantial fraction of the length of the channel.

7. A method as claimed in claim 6, wherein the source for a magnetic field comprises at least one first magnet situated proximal the vapour generator, and at least one second magnet situated distal the vapour generator.

8. A method as claimed in claim 6, wherein the source for a magnetic field comprises an electromagnet.

9. A method as claimed in any one of claim 6, wherein magnetic shielding is disposed between the vapour generator and the plasma generator.

10. A method as claimed in any one of claim 1, in which the substrate is a coated substrate having a surface coating, and the adherent coating forms on the surface coating.

11. A method as claimed in any one of claim 1, in which further layers are applied to the adherent coating by the above method or otherwise.

12. Apparatus for manufacturing by vapour deposition an article comprising at least one adherent coating on a flexible substrate, the apparatus comprising:—
a) at least one ion beam generator comprising
i) a first chamber housing one or more vapour generators capable of forming a vapour from one or more condensed phase sources of material;
ii) a second chamber adjacent the first chamber housing one or more plasma generators comprising
one or more cathodes having one or more open-ended channels extending therethrough, the channels comprising one or more channel walls and having a length extending from one end of the channel to another end of the channel to define one or more spaces
and capable of forming plasma within said one or more spaces;
iii) one or more apertures between the first and second chambers arranged to permit vapour generated in the first chamber to enter the second chamber
the one or more vapour generators and one or more plasma generators being arranged whereby in operation, vapour generated by the one or more vapour generators may traverse the one or more spaces through plasma formed by the one or more plasma generators;
b) at least one gas supply operable to supply gas for conversion into plasma within the at least one ion beam generator
c) at least one substrate receiving region to receive at least one substrate, and permit passage of said substrate across said substrate receiving region and positioned to permit in use at least one substrate passing across the at least one substrate receiving region to be bombarded by ions from the at least one ion beam generator.

13. Apparatus as claimed in claim 12, in which the substrate receiving region comprises a substrate mount permitting passage of the substrate across a support.

14. Apparatus as claimed in claim 12, further comprising a source operable to apply a bias to a substrate passing across the substrate receiving region.

15. Apparatus as claimed in claim 14, wherein the source is operable to apply a radio frequency to a substrate passing across the substrate receiving region.

16. Apparatus as claimed in any one of claim 12 in which a heater is provided to heat the substrate.

17. Apparatus as claimed in any one of claim 12 comprising one or more vents situated between the plasma chamber and the substrate receiving region, and operable to admit gas close to the substrate receiving region.

18. Apparatus as claimed in any one of claim 12, and comprising a source operable to inject gas in the region of the one or more vapour generators to inhibit reaction between reactant gases and at least a surface of the condensed phase sources of material.

19. Apparatus as claimed in any one of claim 12, operable to provide a lower pressure in the first chamber than in the second chamber.

20. Apparatus as claimed in any one of claim 12, comprising a shutter selectively operable to inhibit transfer of vapour from the first chamber to the second chamber.

21. Apparatus as claimed in any one of claim 12, wherein one or more crucibles are provided to house said one or more condensed phase sources of material.

22. Apparatus as claimed in any one of claim 12, comprising a feed spool for a flexible substrate and a take-up spool for the article comprising at least one adherent coating on a flexible substrate.

23. A laminate for use as an electrode for a battery, the laminate comprising an electrically conductive layer capable of acting as a current collector, and one or more layers comprising at least one active layer which comprises one or more solid phases active to absorb and desorb a charge carrying element in operation of the battery,
characterized in that
said at least one active layer is an adherent layer formed by vapour deposition.

24. A method of forming a laminate comprising an electrically conductive layer capable of acting as a current collector, and one or more layers comprising at least one active layer which comprises one or more solid phases active to absorb and desorb a charge carrying element in operation of the battery, wherein said at least one active layer is an adherent layer formed by vapour deposition, the method comprising the steps of:
forming an ion beam comprising one or more elements capable of forming alloys or compounds with an element used as a charge carrying element in a battery; and
bombarding at least one electrically conductive substrate with ions from the ion beam
to form said laminate of at least one active layer and said electrically conductive layer.
